(19) United States
(12) Patent Application Publication
(10) Pub. No.: US 2025/0364939 A1
(43) Pub. Date: Nov. 27, 2025

(54) APPARATUS FOR DETECTING DISCONNECTION OF POWER CABLE OF MOTOR, MOTOR SYSTEM, AND VEHICLE

(71) Applicants: HYUNDAI MOTOR COMPANY, Seoul (KR); KIA CORPORATION, Seoul (KR)

(72) Inventors: Ho Sun JANG, Hwaseong-si (KR); Seong Min KIM, Hwaseong-si (KR); Seung Hyeon BIN, Hwaseong-si (KR); Sang Woo PARK, Hwaseong-si (KR); Byung Oh TAK, Hwaseong-si (KR); Jin Wook KANG, Hwaseong-si (KR); Tae Il YOO, Hwaseong-si (KR); Ho Rim CHOI, Hwaseong-si (KR)

(73) Assignees: HYUNDAI MOTOR COMPANY, Seoul (KR); KIA CORPORATION, Seoul (KR)

(21) Appl. No.: 18/941,463

(22) Filed: Nov. 8, 2024

(30) Foreign Application Priority Data
May 24, 2024 (KR) 10-2024-0067776

(51) Int. Cl. H02P 29/024; B60L 3/00; H02P 21/22; H02P 27/08

(52) U.S. Cl. CPC H02P 29/0243; H02P 21/22; H02P 27/08; B60L 3/003; B60L 3/0061

(57) ABSTRACT

An apparatus for detecting disconnection of a power cable of a motor may include a computing device including a processor and a storage medium on which one or more programs configured to be executable by the processor are recorded, wherein the one or more programs may include: obtaining a plurality of sensing current values from a plurality of current sensors respectively sensing currents flowing in a plurality of windings of the motor corresponding to a plurality of phases of the motor; determining a plurality of correction current values by removing a common mode current from each of the sensing current values; and detecting disconnection in each of the phases based on a cable disconnection index based on the plurality of correction current values.

### CROSS-REFERENCE TO RELATED APPLICATION(S)

The present application claims priority to Korean Patent Application No. 10-2024-0067776 filed on May 24, 2024, the entire contents of which is incorporated herein for all purposes by this reference.

### BACKGROUND OF THE PRESENT DISCLOSURE

### Field of the Present Disclosure

The present disclosure relates to an apparatus for detecting disconnection of a power cable of a motor, a motor system, and a vehicle.

### Description of Related Art

In general, a permanent magnet motor is used as a driving means for an electric vehicle, a hybrid vehicle, a fuel cell vehicle, and the like. An inverter may convert a directional current voltage into a three-phase alternating current voltage (U-phase, V-phase, W-phase) and provide the same to a motor through a power cable, and a motor controller may control the inverter by pulse width modulation (PWM).

However, when a power cable connecting the inverter and the motor is disconnected, not only may the motor not run smoothly, but it may also cause fatal problems such as overcurrent, overvoltage, or damage to the inverter and/or motor.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an apparatus for detecting disconnection of a power cable of a motor, a motor system, and a vehicle.

According to an aspect of the present disclosure, the apparatus for detecting disconnection of a power cable of a motor includes a computing device including a processor and a storage medium on which one or more programs configured to be executable by the processor are recorded, wherein the one or more programs may include instructions for executing: obtaining a plurality of sensing current values from a plurality of current sensors respectively sensing currents flowing in a plurality of windings of the motor corresponding to a plurality of phases of the motor; determining a plurality of correction current values by removing a common mode current from each of the sensing current values; and detecting disconnection in each of the phases based on a cable disconnection index based on the plurality of correction current values.

According to an aspect of the present disclosure, the motor system includes: a first inverter connected to first ends of a plurality of windings of the motor corresponding to a plurality of phases of the motor, and including a plurality of first switching elements; a second inverter connected to second ends of the plurality of windings, and including a plurality of second switching elements; a controller configured for controlling switching of the plurality of first switching elements or the plurality of second switching elements; and a plurality of current sensors respectively sensing currents flowing in the plurality of windings, wherein the controller may be configured to obtain a plurality of sensing current values from the plurality of current sensors, determine a plurality of correction current values by removing a common mode current from each of the sensing current values, and detect a disconnection in each of the phases based on a cable disconnection index based on the plurality of correction current values.

According to an aspect of the present disclosure, the vehicle may include the apparatus for detecting disconnection of a power cable of a motor and/or the motor system, and may travel by the motor system.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF DRAWINGS

FIG. 1A and FIG. 1B are block diagrams illustrating an apparatus for detecting disconnection of a power cable of a motor, a motor system, and a vehicle according to an exemplary embodiment of the present disclosure.

FIG. 2 is a circuit diagram illustrating an apparatus for detecting disconnection of a power cable of a motor and a motor system according to an exemplary embodiment of the present disclosure.

FIG. 3 is a circuit diagram illustrating an apparatus for detecting disconnection of a power cable of a motor and positions of sensors of a motor system according to an exemplary embodiment of the present disclosure.

FIG. 4 is a graph illustrating an apparatus for detecting disconnection of a power cable of a motor and a plurality of sensing current values detected by a plurality of current sensors of a motor system according to an exemplary embodiment of the present disclosure.

FIG. 5 is a block diagram illustrating an apparatus for detecting disconnection of a power cable of a motor and a control logic of a controller of a motor system according to an exemplary embodiment of the present disclosure.

FIG. 6 is a flowchart illustrating an apparatus for detecting disconnection of a power cable of a motor and operations performed by a motor system according to an exemplary embodiment of the present disclosure.

FIG. 7A illustrates current values in a stationary reference frame when a U-phase power cable is disconnected, when a V-phase power cable is disconnected, and when a W-phase power cable is disconnected.

FIG. 7B illustrates a cable disconnection index when the U-phase power cable is disconnected, when the V-phase power cable is disconnected, and when the W-phase power cable is disconnected.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Since the present disclosure may have various changes and may have various exemplary embodiments of the present disclosure, specific embodiments may be illustrated in the drawings and described in detail. However, this is not intended to limit the present disclosure to specific embodiments, it should be understood to include all modifications, equivalents, and substitutes included in the spirit and technical scope of the present disclosure.

Terms such as first, second, and the like may be used to describe various elements, but the elements should not be limited by the terms. The above terms may be used only for distinguishing one component from another. For example, without departing from the scope of the present disclosure, a first component may be referred to as a second component, and similarly, a second component may also be referred to as a first component. The term “and/or” may include a combination of a plurality of related listed items or any of the plurality of related listed items.

The terms used in the present application may be only used to describe specific embodiments, and are not intended to limit the present disclosure. The singular expression may include the plural expression, unless the context clearly dictates otherwise. In the present application, it should be understood that terms such as “include,” “comprise,” or “have” are intended to designate that features, numerals, steps, operations, components, parts, or combination thereof described in the specification exists, but one or more other features this does not preclude the existence or addition of numbers, steps, operations, components, parts, or combinations thereof.

Unless defined otherwise, all terms used herein, including technical or scientific terms, the same include the same meaning as that which can commonly understood by one of ordinary skill in the art to which the present disclosure belongs. Terms such as those defined in a commonly used dictionary should be interpreted as including a meaning consistent with the meaning in the context of the related art, and should not be interpreted in an ideal or excessively formal manner unless explicitly defined in the present application.

In the present specification, a vehicle (including an electric vehicle) refers to a variety of vehicles for moving an object to be transported, such as people, animals, or goods, from a starting point to a destination. These vehicles are not limited to vehicles that run on roads or tracks.

Hereinafter, exemplary embodiments of the present disclosure will be described in more detail with reference to the accompanying drawings.

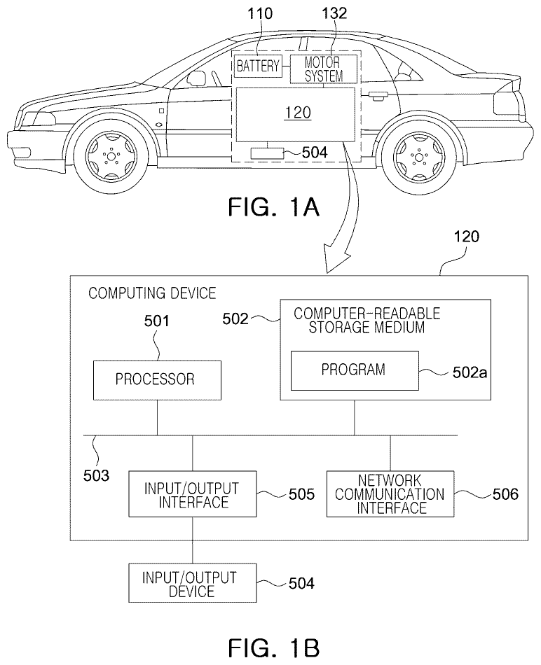

Referring to FIGS. 1A and 1B, an apparatus for detecting disconnection of a power cable of a motor according to an exemplary embodiment of the present disclosure may include a computing device 120 and/or a motor system 132, and may be included in a vehicle (EV).

The motor system 132 may receive power from a battery 110 and apply a torque to wheels of the vehicle (EV). Depending on the design, the motor system 132 may be configured to generate energy by performing regenerative braking on the rotating wheels and supply the generated energy to the battery 110.

The vehicle (EV) may be implemented as one of, a hybrid vehicle (HEV), a plug-in hybrid vehicle (HEV), an electric vehicle, and a fuel cell electric vehicle (FCEV), but the present disclosure is not limited thereto.

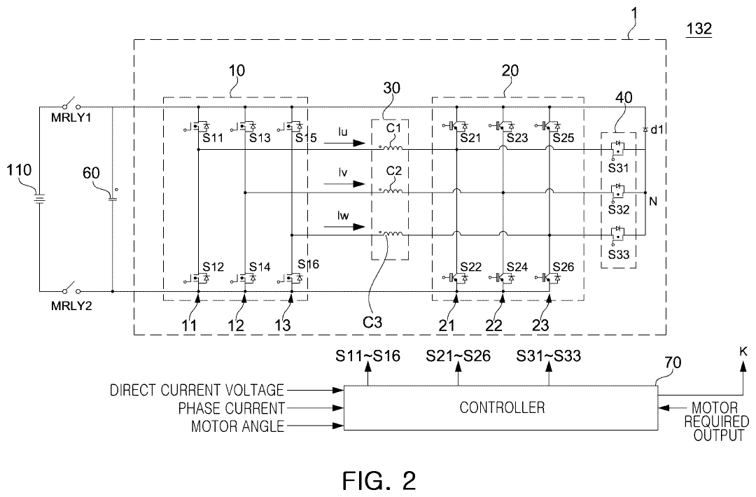

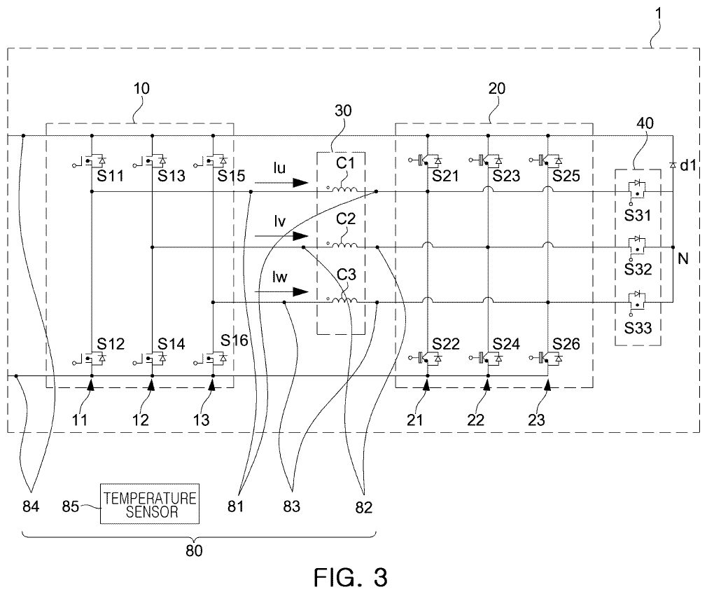

Referring to FIG. 2 and FIG. 3, the motor system 132 according to an exemplary embodiment of the present disclosure may include a first inverter 10, a second inverter 20, a controller 70, and a sensor unit 80, and may be configured for controlling a motor 30. For example, similarly to the computing device 120, the controller 70 may include at least one of a processor, a computer-readable storage medium, a communication bus, an input/output interface, a communication interface, and an input/output device.

The motor 30 may include a plurality of windings C1, C2, and C3, and may be included in a motor system 132. For example, the motor 30 may be implemented as an induction motor, a permanent magnet synchronous motor, and the like. A magnetic field based on currents flowing in the plurality of windings C1, C2, and C3 may apply a force to magnetic field elements of the motor 30 to rotate the motor 30. As the motor 30 rotates, the wheels of the vehicle may also rotate.

The first inverter 10 may be connected to first ends of the plurality of windings C1, C2, and C3 corresponding to a plurality of phases (U-phase, V-phase, and W-phase) of the motor 30, and include a plurality of first switching elements S11, S12, S13, S14, S15, and S16. A phase difference between the plurality of phases (U-phase, V-phase, and W-phase) may be 120 degrees.

The first inverter 10 may be electrically connected to the battery 110, and a direct current voltage of the battery 110 may be transmitted to the first inverter 10 through a direct current link capacitor 60. The first inverter 10 may convert the direct current voltage into alternating current phase currents Iu, Iv, and Iw based on on-off switching of the plurality of first switching elements S11, S12, S13, S14, S15, and S16. The alternating phase currents Iu, Iv, and Iw may flow to the plurality of windings C1, C2, and C3 through power cables.

The second inverter 20 may be connected to second ends of the plurality of windings C1, C2, and C3, and include a plurality of second switching elements S21, S22, S23, S24, S25, and S26. The second inverter 20 may be electrically connected to the battery 110 through the first inverter 10, and convert the direct current voltage into alternating current phase currents Iu, Iv, and Iw based on on-off switching of the plurality of second switching elements S21, S22, S23, S24, S25, and S26. The alternating phase currents Iu, Iv, and Iw may flow to a plurality of windings C1, C2, and C3 through the power cables.

Each of the first plurality of switching elements S11, S12, S13, S14, S15, and S16 and the plurality of second switching elements S21, S22, S23, S24, S25, and S26 may include a power semiconductor device such as an insulated gate bipolar transistor (IGBT) and a diode, the power semiconductor device may switch whether there is an electrical connection between an emitter terminal and a collector terminal based on a signal from a gate terminal, and the diode may be connected between the emitter terminal and the collector terminal.

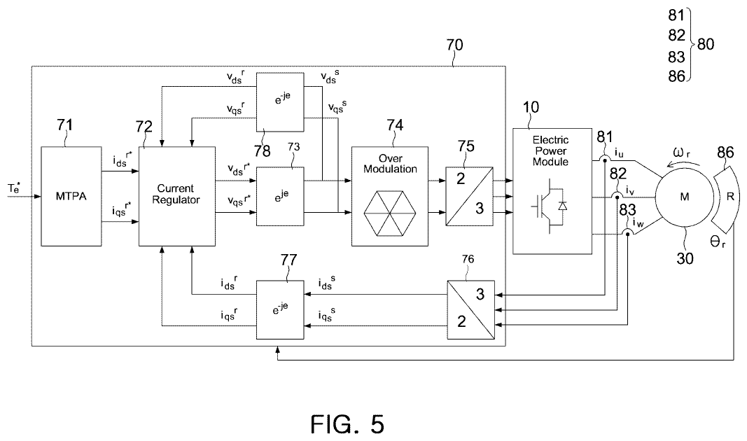

The sensor unit 80 may include at least one of a plurality of current sensors 81, 82, and 83, a voltage sensor 84, a temperature sensor 85, and a rotation sensor (86 in FIG. 5). The voltage sensor 84 may detect a direct current voltage between the battery 110 and the first inverter 10, and the temperature sensor 85 may detect a temperature of each of the first switching elements S11, S12, S13, S14, S15, and S16 and the plurality of second switching elements S21, S22, S23, S24, S25, and S26.

For example, sensing temperature values of the temperature sensor 85 may be transmitted to the computing device 120 of FIG. 1A and FIG. 1B, and the computing device 120 may be configured for controlling whether to turn relays MRLY1 and MRLY2 on or off, based on the sensing temperature values. The battery 110 may provide energy to the first and second inverters 10 and 20 when the relays MRLY1 and MRLY2 which may be included in the battery 110 are in the on-state, and the relays MRLY1 and MRLY2 may block energy transfer between the first and second inverters 10 and 20 and the battery 110 when the relays MRLY1 and MRLY2 are in the off-state.

The plurality of current sensors 81, 82, and 83 may respectively detect currents Iu, Iv, and Iw flowing in the plurality of windings C1, C2, and C3. For example, the plurality of current sensors 81, 82, and 83 may be disposed on power cables extending from the plurality of windings C1, C2, and C3 to the first converter 10, and may also be disposed on power cables extending from the plurality of windings C1, C2, and C3 to the second converter 20.

The controller 70 may obtain a plurality of sensing current values from the plurality of current sensors 81, 82, and 83, obtain a sensing current voltage value from the voltage sensor 84, obtain a sensing motor angle value from the rotation sensor (86 of FIG. 5), and receive a motor required output value. For example, the controller 70 may receive a motor required output value from the computing device 120 of FIG. 1A and FIG. 1B.

The controller 70 may be configured for controlling switching of a plurality of first switching elements S11, S12, S13, S14, S15, and S16 and/or a plurality of second switching elements S21, S22, S23, S24, S25, and S26 based on the obtained sensing values and the motor required output value. For example, the controller 70 may be configured for controlling the switching by transmitting a signal to the gate terminal of the power semiconductor device. For example, the controller 70 may be configured for controlling the switching using pulse width modulation (PWM). For example, the PWM method may include space vector pulse width modulation (SVPWM) control and remote state pulse width modulation (RSPWM) control, but the present disclosure is not limited thereto.

Referring to FIG. 2 and FIG. 3, the motor system 132 according to an exemplary embodiment of the present disclosure may further include a motor mode change unit 40 that can change between an Open End (OEW) mode and a Closed End (CEW) mode. The motor mode change unit 40 may include a plurality of third switches S31, S32, and S33 connected between the plurality of windings C1, C2, and C3.

When the plurality of third switches S31, S32, and S33 are in the on-state, the plurality of windings C1, C2, and C3 may be directly connected to each other, and the plurality of windings C1, C2, and C3 may form a Y-connection. That is, the inverter system 1 can operate in the Closed End (CEW) mode. In the instant case, the controller 70 may be configured for controlling the switching the plurality of first switching elements S11, S12, S13, S14, S15, and S16, and may not control the switching of the plurality of second switching elements S21, S22, S23, S24, S25, and S26. Accordingly, the inverter system 1 may operate in a mode using only the first inverter 10 among the first and second inverters 10 and 20.

When the plurality of third switches S31, S32, S33 are in the off-state, the plurality of windings C1, C2, and C3 may not be directly connected to each other, and the inverter system 1 may operate in the Open End (OEW) mode. In the instant case, the controller 70 may be configured for controlling all of the switching of the plurality of first switching elements S11, S12, S13, S14, S15, and S16 and the plurality of second switching elements S21, S22, S23, S24, S25, and S26. Accordingly, the inverter system 1 can operate in a mode using both the first and second inverters 10 and 20, and the battery 110 is used commonly in the first inverter 10 and the second inverter 20.

The controller 70 may switch the mode of the inverter system 1 by controlling on-off switching of the plurality of third switches S31, S32, and S33. Depending on the design, computing device 120 of FIG. 1 may switch the mode of inverter system 1 directly or through the controller 70. Depending on the design, the motor mode change unit 40 may be omitted, and the inverter system 1 may operate only in the OEW mode among the CEW mode and OEW mode.

As compared to the case in which the inverter system 1 operates in the CEW mode, current values of the inverter system 1, operating in the OEW mode may be larger overall, and the motor 30 may convert electrical energy into a torque more efficiently. However, unlike in the CEW mode, since the inverter system 1 operating in the OEW mode does not include a Y-connection for cancelling out a common mode factor, which may cause a common mode factor, the inverter system 1 operating in the OEW mode may cause a common mode factor due to a slight difference in impedance between the first and second inverters 10 and 20 and a slight difference in switching timing according to the difference.

For example, the common mode voltage (V_{c}) caused by a difference in combined voltage and dead time of the first inverter 10 and the second inverter 20 of the inverter system 1 operating in the OEW mode may be defined by the following Equation 1. Here, Vₐₙ₁, V_{bn1}, and V_{cn1} are voltages for each phase of the first inverter 10, and Vₐₙ₂, V_{bn2}, and V_{cn2} are voltages for each phase of the second inverter 20.

$${V}_{c 1} = ( {V}_{an 1} + {V}_{bn 1} + {V}_{cn 1} ) / 3 \qquad [ Equation 1 ]$$

$${V}_{c 2} = ( {V}_{an 2} + {V}_{bn 2} + {V}_{cn 2} ) / 3$$

$${V}_{c} = {V}_{c 1} - {V}_{c 2}$$

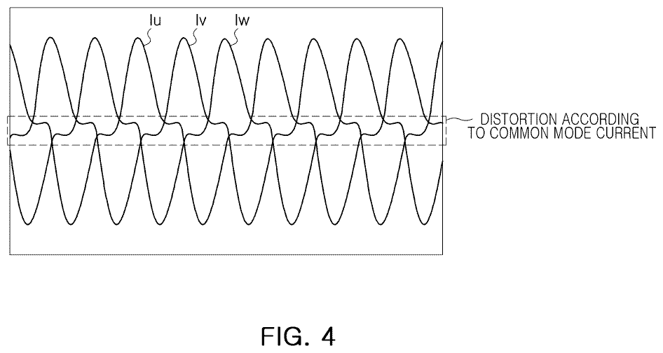

The common mode voltage (V_{c}) can cause a common mode current. Referring to FIG. 4, waveforms of the currents Iu, Iv, and Iw detected by a plurality of sensors (81, 82, and 83 of FIG. 3) may include distortion concentrated in a range in which absolute values of the currents Iu, Iv, and Iw are close to 0. The distortion may be distortion due to common mode current. When the detected currents Iu, Iv, and Iw are used as is to detect disconnection of the power cable, the accuracy for detecting disconnection may be reduced.

Since a common mode current may be removed from the currents Iu, Iv, and Iw detected by the plurality of sensors (81, 82, and 83 in FIG. 3), in the apparatus for detecting disconnection of a power cable of a motor and the motor system 132 according to an exemplary embodiment of the present disclosure may improve the accuracy for detecting disconnection of a power cable regardless of the mode of the inverter system 1, or improve the accuracy for detecting disconnection of a power cable when the inverter system 1 operates in the OEW mode.

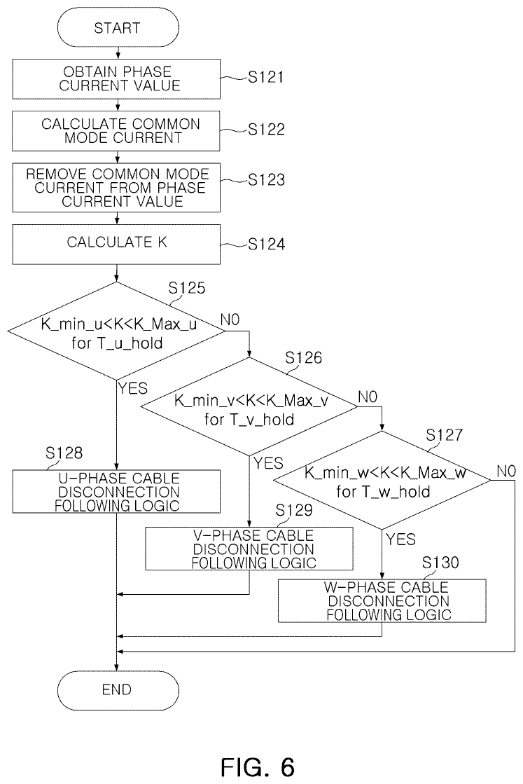

Referring to FIGS. 2, 3, and 6, the apparatus for detecting disconnection of a power cable of a motor according to an exemplary embodiment of the present disclosure may perform operations of obtaining a plurality of sensing current values from a plurality of current sensors 81, 82, and 83 respectively sensing currents Iu, Iv, and Iw, flowing in a plurality of windings C1, C2, and C3 corresponding to a plurality of phases (U-phase, V-phase, and W-phase) of the motor 30 (S121), determining a common mode current from the plurality of sensing current values (S122), determining a plurality of correction current values by removing the common mode current from each of the sensing current values (S123), determining a cable disconnection index (K) based on current values in a stationary reference frame from the plurality of correction current values (S124), and detecting disconnection in each of the phases based on the cable disconnection index (K) (S125, S126, and S127). The determining a plurality of correction current values (S123) may include determining a common mode current (S122), and the detecting a disconnection (S125, S126, S127) may include determining a cable disconnection index (K)(S124).

The operations may be performed by computing device 120 of FIG. 1A and FIG. 1B. Depending on the design, the controller 70 of the motor system 132 of FIG. 2 instead of the computing device 120 of FIG. 1 may perform the above-described operations.

In the determining a common mode current (S122), the apparatus for detecting disconnection of a power cable of a motor and/or controller 70 may be configured to determine a common mode current (In) according to the following Equation 2. Here, Iu, Iv, and Iw may be U-phase, V-phase, and W-phase current values detected from the plurality of current sensors 81, 82, and 83, respectively.

$${I}_{n} = \frac{{I}_{u} + {I}_{v} + {I}_{w}}{3} \qquad [ Equation 2 ]$$

In the determining a plurality of correction current values (S123), the apparatus for detecting disconnection of a power cable of a motor and/or controller 70 may be configured to determine a plurality of correction current values (I′u, I′v, and I′w).

$${I}_{u}^{′} = {I}_{u} - {I}_{n} , {I}_{v}^{′} = {I}_{v} - {I}_{n} , {I}_{w}^{′} = {I}_{w} - {I}_{n} \qquad [ Equation 3 ]$$

In the determining a cable disconnection index (K) (S124), the apparatus for detecting disconnection of a power cable of a motor and/or controller 70 may be configured to determine a d-axis current (Idss) and a q-axis current (Iqss) in a stationary reference frame from the plurality of correction current values (I′u, I′v, and I′w) according to the following Equation 4.

$$[ \begin{matrix}Idss \\ Iqss\end{matrix} ] = [ \begin{matrix}\frac{2}{3} & \frac{- 1}{3} & \frac{- 1}{3} \\ 0 & \frac{1}{\sqrt{3}} & \frac{- 1}{\sqrt{3}}\end{matrix} ] [ \begin{matrix}{I}^{′} u \\ {I}^{′} v \\ {I}^{′} w\end{matrix} ] \qquad [ Equation 4 ]$$

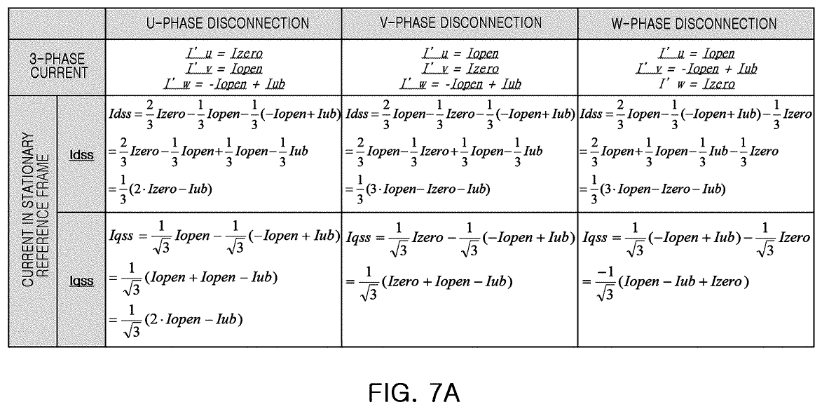

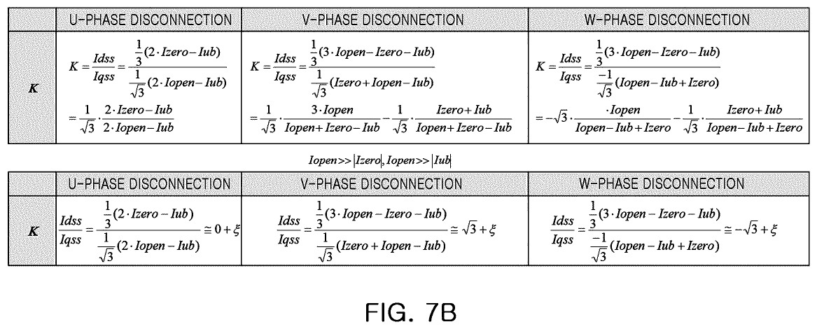

The apparatus for detecting disconnection of a power cable of a motor and/or controller 70 may store in advance the d-axis current (Idss) and q-axis current (Iqss) in the stationary reference frame, when the U-phase power cable is disconnected, the V-phase power cable is disconnected, and the W-phase power cable is disconnected. The apparatus for detecting disconnection of a power cable of a motor and/or controller 70 may store in advance the d-axis current (Idss) and q-axis current (Iqss) in the stationary reference frame determined in advance according to Equations of FIG. 7A, or determine the d-axis current (Idss) and q-axis current (Iqss) in the stationary reference frame according to the Equations of FIG. 7A. In FIG. 7A, since Izero is a current value of a disconnected phase (ideally 0), and Iopen is a current value of one of two non-disconnected phases, a current value of the other one of the two non-disconnected phases may be −Iopen. The total sum of the three phase current values is ideally 0. Here, assuming that there is an unbalanced current between the three phases, Iub is an unbalanced current.

Thereafter, in the determining a cable disconnection index (K) (S124), the apparatus for detecting disconnection of a power cable of a motor and/or controller 70 may be configured to determine the cable disconnection index (K) according to the following Equation 5.

$$K = \frac{Idss}{Iqss} \qquad [ Equation 5 ]$$

The apparatus for detecting disconnection of a power cable of a motor and/or controller 70 may store in advance a cable disconnection index (K), when the U-phase power cable is disconnected, the V-phase power cable is disconnected, and the W-phase power cable is disconnected. The apparatus for detecting disconnection of a power cable of a motor and/or controller 70 may store in advance the cable disconnection index (K) determined in advance according to Equations in FIG. 7B, or determine the cable disconnection index (K) according to the Equations in FIG. 7B.

In FIG. 7B, since an absolute value of Iopen may be much greater than an absolute value of Izero and may be much greater than an absolute value of Iub, the cable disconnection index (K), when the U-phase power cable is disconnected, may be as close to 0 as an error range (corresponding to special characters), the cable disconnection index (K), when the V-phase power cable is disconnected, may be as close to a positive number of a square root of 3 as the error range (corresponding to special characters), and when the W-phase power cable is disconnected, may be as close to a negative number of a square root of 3 as the error range (corresponding to special characters in FIG. 7B).

Therefore, a U-phase disconnection detection reference range may include 0, a V-phase disconnection detection reference range may include a positive number of a square root of 3, a W-phase disconnection detection reference range may include a negative number of a square root of 3, which may be stored in advance in the apparatus for detecting disconnection of a power cable of a motor and/or controller 70, or determined by the apparatus for detecting disconnection of a power cable of a motor and/or controller 70.

In the operations of detecting a disconnection (S125, S126, and S127), the apparatus for detecting disconnection of a power cable of a motor and/or controller 70 may include determining that disconnection of the U-phase has occurred, when the determined cable disconnection index (K) falls within the U-phase disconnection detection reference range for a predetermined time period (e.g., 30 ms), determining that disconnection of the V-phase has occurred, when the determined cable disconnection index (K) falls within the V-phase disconnection detection reference range for a predetermined time period (e.g., 30 ms), and determining that disconnection of the W-phase has occurred, when the determined cable disconnection index (K) falls within the W-phase disconnection detection reference range for a predetermined time period (e.g., 30 ms).

Here, since the U-phase disconnection detection reference range, the V-phase disconnection detection reference range, and the W-phase disconnection detection reference range may not overlap with each other, the apparatus for detecting disconnection of a power cable of a motor and/or the controller 70 may be configured to determine that a phase in which a disconnection has occurred is a U-phase, V-phase, and W-phase, depending on what value the cable disconnection index (K), hardly changing for a predetermined time period (e.g., 30 ms), is close to.

Depending on the design, the apparatus for detecting disconnection of a power cable of a motor and motor system according to an exemplary embodiment of the present disclosure may further perform operations of performing following logics (S128, S129, and S130), when disconnection is detected by the operations of detecting disconnection in each of phases (S125, S126, and S127). For example, the operations of performing following logics (S128, S129, and S130) may include transmitting information of disconnection of a power cable of a motor to a vehicle (EV in FIG. 1) or outside of the vehicle (e.g., external network, and server). Accordingly, the driver or vehicle manager may accurately recognize that disconnection has occurred in a power cable of a predetermined phase of the vehicle's motor system.

Meanwhile, referring to FIGS. 2 and 5, the controller 70 of the motor system 132 according to an exemplary embodiment of the present disclosure may be configured for controlling switching of a plurality of first switching elements (S11, S12, S13, S14, S15, and S16) and/or a plurality of second switching elements (S21, S22, S23, S24, S25, and S26) based on the plurality of correction current values (I′u, I′v, and I′w) described above.

The controller 70 may convert the plurality of correction current values (I′u, I′v, and I′w) into current values in a synchronous reference frame (idsr and iqsr), determine a pulse width modulation (PWM) duty based on the current values in the synchronous reference frame (idsr and iqsr), and control the switching of the plurality of first switching elements (S11, S12, S13, S14, S15, and S16) and/or the plurality of second switching elements (S21, S22, S23, S24, S25, and S26) based on the PWM duty.

For example, the controller 70 may include a current command map 71, a current control unit 72, a first coordinate conversion unit 73, a pulse width modulation unit 74, a phase conversion unit 75, a phase current conversion unit 76, a second coordinate conversion unit 77 and a third coordinate conversion unit 78.

The phase current converter 76 may obtain a plurality of sensing current values (Iu, Iv, and Iw) from the plurality of current sensors 81, 82, and 83, determine a common mode current In from the plurality of sensing current values (Iu, Iv, and Iw) determine a plurality of correction current values (I′u, I′v, and I′w) by removing the common mode current In from each of the sensing current values (Iu, Iv, and Iw), and convert the plurality of correction current values (I′u, I′v, and I′w) into current values in a stationary reference frame (idss and iqss).

The second coordinate conversion unit 77 may convert the current values in the stationary reference frame (idss and iqss) into current values in a synchronous reference frame (idsr and iqsr) and provide the converted current values in the stationary reference frame (idss and iqss) to a current control unit 72. For example, the second coordinate conversion unit 77 may obtain a sensing motor angle (Or) from the rotation sensor 86, and may apply the trigonometric function of the sensing motor angle (Or) to the current values in the stationary reference frame (idss and iqss) and convert the same into current values in the synchronous reference frame (idsr and iqsr).

The current command map 71 may be configured to generate corresponding current commands (Ids^{r*}and Iqs^{r*}) based on the motor required output (motor required torque (Te*) and the back electromotive force of the motor generated by the driver's operation, or the like.

The current control unit 72 may be configured to generate voltage commands (Vds^{r*} and Vqs^{r*}) that can reduce a difference obtained by receiving current commands (Ids^{r*} and Iqs^{r*}) and comparing the current provided to the actual motor with the detected value. Since the current control unit 72 may receive current values in a synchronous reference frame (idsr and iqsr), output signals of the current control unit 72 and the pulse width modulator 74 may be determined based on the current values in the synchronous reference frame (idsr and iqsr). Accordingly, the controller 70 may be configured for controlling the motor 30 more accurately, further improving the lifespan of the motor 30.

The first coordinate conversion unit 73 may convert the voltage commands in a synchronous reference frame (Vds^{r*} and Vqs^{r*)} into voltages in a stationary reference frame (Vdss and Vqss), and the third coordinate conversion unit 78 may convert the voltages in the stationary reference frame (Vdss and Vqss) into voltages in a synchronous reference frame (Vdsr and Vqsr) and feed the same back to the current control unit 72.

The pulse width modulation unit 74 may be configured for controlling switching of a plurality of switching elements of the first inverter 10 and/or the second inverter using pulse width modulation (PWM). For example, the PWM method may include space vector pulse width modulation (SVPWM) control and remote state pulse width modulation (RSPWM) control, but the present disclosure is not limited thereto. The phase converter 75 can convert an output signal in the stationary reference frame of the pulse width modulator 74 into a control signal for each phase.

Meanwhile, referring to FIG. 1A and FIG. 1B, the apparatus for detecting disconnection of a power cable of a motor according to an exemplary embodiment of the present disclosure may include a computing device 500 disposed in a vehicle (EV), and the computing device 500 may include at least one processor 501, a computer-readable storage medium 502, and a communication bus 503. The communication bus 503 may interconnect various other components of the computing device 500, including the processor 501 and the computer-readable storage medium 502.

The processor 501 may cause the computing device 500 to operate according to the above-described exemplary embodiments of the present disclosure. For example, the processor 501 may execute one or more programs stored in the computer-readable storage medium 502. The one or more programs may include one or more computer executable instructions, wherein, when executed by the processor 501, the computer-readable executable instructions may be configured to cause the computing device 500 to perform operations according to an exemplary embodiment of the present disclosure.

The computer-readable storage medium 502 may be configured to store computer-executable instructions or program code, program data, and/or other suitable forms of information. A program 502a stored on the computer-readable storage medium 502 includes a set of instructions executable by the processor 501. In an exemplary embodiment of the present disclosure, the computer-readable storage medium 502 may include a memory (a volatile memory such as a random access memory, a non-volatile memory, or a suitable combination thereof), one or more magnetic disk storage devices, optical disk storage devices, flash memory devices, other forms of storage media which may be accessed by the computing device 500 and store target information, or suitable combinations thereof.

The computing device 500 may also include one or more input/output interfaces 505 and one or more network communication interfaces 506 providing an interface for one or more input/output devices 504. The input/output interface 505 and the network communication interface 506 are connected to the communication bus 503. The network may be one of a cellular network, such as a global system for mobile communications (GSM), enhanced data rates for GSM evolution (EDGE), a general packet radio service (GPRS), a Code Division Multiple Access (CDMA), a time division CDMA (TD-CDMA), a Universal Mobile Telecommunications System (UMTS), a Long Term Evolution (LTE), or another cellular network.

The input/output device 504 may be connected to other components of the computing device 500 through the input/output interface 505. The exemplary input/output device 504 may include an input device such as a pointing device (a mouse, a trackpad, or the like), a keyboard, a touch input device (a touchpad, a touchscreen, or the like), a voice or sound input device, various types of sensor devices, and/or an imaging device, and an output device such as a display device, a printer, a speaker, and/or a network card. The exemplary input/output device 504 may be included inside the computing device 500 as a component forming the computing device 500, or may be connected to the computing device 500 as a separate device, distinct from the computing device 500.

Meanwhile, various exemplary embodiments of the present disclosure may include a program for performing the methods described in the present specification on a computer, and a computer readable recording medium including the program. The non-transitory computer-readable recording medium may include program instructions, local data files, local data structures, or the like, alone or in a combination thereof. The medium may be specially designed and configured for the present disclosure, or may be commonly available in the field of computer software. Examples of the computer-readable medium may include a hardware device specially configured to store a magnetic medium such as hard disks, floppy disks and magnetic tapes, an optical recording medium such as CD-ROMs and DVDs, and program instructions such as ROM, RAM, and a flash memory and perform the same. Examples of the program may include not only machine language codes generated by a compiler, but also high-level language codes which may be executed by a computer using an interpreter.

As set forth above, according to an exemplary embodiment of the present disclosure, in an apparatus for detecting disconnection of a power cable of a motor, a motor system, and a vehicle, accuracy for detecting disconnection of a power cable may be improved, regardless of a mode (or a structure) of an inverter system, and the accuracy for detecting disconnection of a power cable when the inverter system operates in an Open End (OEW) mode (or in an OEW structure) may be improved.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Software implementations may include software components (or elements), object-oriented software components, class components, task components, processes, functions, attributes, procedures, subroutines, program code segments, drivers, firmware, microcode, data, database, data structures, tables, arrays, and variables. The software, data, and the like may be stored in memory and executed by a processor. The memory or processor may employ a variety of means well known to a person including ordinary knowledge in the art.

Furthermore, the terms such as “unit”, “module”, etc. included in the specification mean units for processing at least one function or operation, which may be implemented by hardware, software, or a combination thereof.

In the flowchart described with reference to the drawings, the flowchart may be performed by the controller or the processor. The order of operations in the flowchart may be changed, a plurality of operations may be merged, or any operation may be divided, and a predetermined operation may not be performed. Furthermore, the operations in the flowchart may be performed sequentially, but not necessarily performed sequentially. For example, the order of the operations may be changed, and at least two operations may be performed in parallel.

Hereinafter, the fact that pieces of hardware are coupled operatively may include the fact that a direct and/or indirect connection between the pieces of hardware is established by wired and/or wirelessly.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An apparatus for detecting disconnection of a power cable of a motor, comprising:
a computing device including a processor and a storage medium on which one or more programs configured to be executable by the processor are recorded;
wherein by use of the one or more programs, the computing device performs:
obtaining a plurality of sensing current values from a plurality of current sensors respectively sensing currents flowing in a plurality of windings of the motor corresponding to a plurality of phases of the motor;
determining a plurality of correction current values by removing a common mode current from each of the sensing current values; and
detecting the disconnection in each of the phases based on a cable disconnection index based on the plurality of correction current values.

2. The apparatus of claim 1,
wherein the common mode current corresponds to an average value of the plurality of sensing current values, and
wherein the cable disconnection index is based on current values in a stationary reference frame of the plurality of correction current values.

3. The apparatus of claim 2, wherein the detecting of the disconnection includes
determining that a U-phase disconnection has occurred, in response that the cable disconnection index falls within a U-phase disconnection reference range for a predetermined time period,
determining that a V-phase disconnection has occurred, in response that the cable disconnection index falls within a V-phase disconnection detection reference range for a predetermined time period,
determining that a W-phase disconnection has occurred, in response that the cable disconnection index falls within a W-phase disconnection detection reference range for a predetermined time period,
wherein the U-phase disconnection detection reference range, the V-phase disconnection detection reference range, and the W-phase disconnection detection reference range do not overlap each other.

4. The apparatus of claim 2, wherein the detecting of the disconnection includes:
determining the cable disconnection index based on a value obtained by dividing a q-axis current by a d-axis current in a stationary reference frame.

5. The apparatus of claim 4, wherein the detecting of the disconnection further includes:
determining that a U-phase disconnection has occurred, in response that the cable disconnection index falls within a U-phase disconnection detection reference range for a predetermined time period,
determining that a V-phase disconnection has occurred, in response that the cable disconnection index falls within a V-phase disconnection detection reference range for a predetermined time period,
determining that a W-phase disconnection has occurred, in response that the cable disconnection index falls within a W-phase disconnection detection reference range for a predetermined time period,
wherein the U-phase disconnection detection reference range, the V-phase disconnection detection reference range, and the W-phase disconnection detection reference range do not overlap with each other,
wherein the U-phase disconnection detection reference range includes 0,
wherein the V-phase disconnection detection reference range includes a positive number of a square root of 3, and
wherein the W-phase disconnection detection reference range includes a negative number of the square root of 3.

6. The apparatus of claim 1, wherein the computing device further performs:
executing a following logic in response that the disconnection is detected by operation of detecting disconnection in each of the phases,
wherein the executing of the following logic includes transmitting information of disconnection of the power cable of the motor to a vehicle or an outside of the vehicle.

7. The apparatus of claim 1, further including:
a motor system including the motor, a first converter, a second converter, the plurality of current sensors, and a controller,
wherein the first inverter is connected to first ends of the plurality of windings, and includes a plurality of first switching elements,
wherein the second inverter is connected to second ends of the plurality of windings, and includes a plurality of second switching elements, and
wherein the controller operatively connected to the plurality of first switching elements or the plurality of second switching elements is configured to control switching of the plurality of first switching elements or the plurality of second switching elements.

8. The apparatus of claim 7, further including:
a plurality of third switching elements connected between the plurality of windings.

9. The apparatus of claim 8, further including:
a battery commonly used in the first inverter and the second inverter.

10. The apparatus of claim 7, wherein the controller is further configured to convert the plurality of correction current values into current values in a synchronous reference frame, to determine a pulse width modulation (PWM) duty based on the current values in the synchronous reference frame, and to control switching of the plurality of first switching elements or the plurality of second switching elements based on the PWM duty.

11. A vehicle, comprising:
the apparatus of claim 1.

12. A motor system, comprising:
a first inverter connected to first ends of a plurality of windings of a motor corresponding to a plurality of phases of the motor, and including a plurality of first switching elements;
a second inverter connected to second ends of the plurality of windings, and including a plurality of second switching elements;
a controller operatively connected to a plurality of first switching elements or a plurality of second switching elements and configured for controlling switching of the plurality of first switching elements or the plurality of second switching elements; and
a plurality of current sensors respectively sensing currents flowing in the plurality of windings,
wherein the controller operatively connected to the plurality of current sensors is configured to obtain a plurality of sensing current values from the plurality of current sensors, determine a plurality of correction current values by removing a common mode current from each of the sensing current values, and detect disconnection in each of the phases based on a cable connection index based on the plurality of correction current values.

13. The motor system of claim 12,
wherein the common mode current corresponds to an average value of the plurality of sensing current values, and
wherein the cable disconnection index is based on current values in a stationary reference frame of the plurality of correction current values.

14. The motor system of claim 12, wherein the controller is further configured to convert the plurality of correction current values into current values in a synchronous reference frame, to determine a pulse width modulation (PWM) duty based on the current values in the synchronous reference frame, and to control the switching of the plurality of first switching elements or the plurality of second switching elements based on the PWM duty.

15. The motor system of claim 13,
wherein the controller is further configured to:
determine that a U-phase disconnection has occurred, in response that the cable disconnection index falls below a U-phase disconnection detection reference range for a predetermined time period,
determine that a V-phase disconnection has occurred, in response that the cable disconnection index falls within a V-phase disconnection detection reference range for a predetermined time period,
determine that a W-phase disconnection has occurred, in response that the cable disconnection index falls within a W-phase disconnection detection reference range for a predetermined time period, and
wherein the U-phase disconnection detection reference range, the V-phase disconnection detection reference range, and the W-phase disconnection detection reference range do not overlap each other.

16. The motor system of claim 13, wherein the controller is further configured to determine the cable disconnection index based on a value obtained by dividing a q-axis current by a d-axis current in a stationary reference frame.

17. The motor system of claim 16,
wherein the controller is further configured to:
determine that a U-phase disconnection has occurred, in response that the cable disconnection index falls within a U-phase disconnection detection reference range for a predetermined time period,
determine that a V-phase disconnection has occurred, in response that the cable disconnection index falls within a V-phase disconnection detection reference range for a predetermined time period,
determine that a W-phase disconnection has occurred, in response that the cable disconnection index falls within a W-phase disconnection detection reference range for a predetermined time period,
wherein the U-phase disconnection detection reference range, the V-phase disconnection detection reference range, and the W-phase disconnection detection reference range do not overlap with each other,
wherein the U-phase disconnection detection reference range includes 0,
wherein the V-phase disconnection detection reference range includes a positive number of a square root of 3, and
wherein the W-phase disconnection detection reference range includes a negative number of the square root of 3.

18. The motor system of claim 12, further including:
a plurality of third switching elements connected between the plurality of windings.

19. The motor system of claim 18, further including:
a battery commonly used in the first inverter and the second inverter.

20. A vehicle that travels using the motor system of claim 12.
